(19) United States
(12) Patent Application Publication
(10) Pub. No.: US 2023/0299550 A1
(43) Pub. Date: Sep. 21, 2023

(54) LOW-STRAIN MOUNTING METHOD FOR A TRANSPORTABLE OPTICAL RESONATOR

(71) Applicant: AOSense, Inc., Fremont, CA (US)

(72) Inventors: Miao Zhu, San Jose, CA (US); Brenton C. Young, Palo Alto, CA (US); Douglas Ritchie Harvey, San Mateo, CA (US); Thang Quoc Tran, San Jose, CA (US); Kisra Nayomal Egodapitiya, Sunnyvale, CA (US)

(21) Appl. No.: 18/178,436

(22) Filed: Mar. 3, 2023

Related U.S. Application Data
(60) Provisional application No. 63/317,795, filed on Mar. 8, 2022.

(51) Int. Cl. H01S 3/08; H01S 3/02

(52) U.S. Cl. CPC H01S 3/08; H01S 3/025; H01S 3/08059

(57) ABSTRACT

The system includes an optical resonator, a mount, and a fastener. The optical resonator is comprised of a material with a horizontal plane symmetry. The optical resonator includes a horizontal plane protrusion for mounting. The horizontal plane protrusion includes discrete resonator rotational orientation positions. The mount comprises mounting legs compatible with the horizontal plane symmetry. The mount includes discrete mount rotational orientation positions that correspond to the discrete resonator rotation orientation positions at a plurality of rotational angles. The fastener secures the horizontal plane protrusion of the optical resonator to the mount.

### CROSS REFERENCE TO OTHER APPLICATIONS

This application claims priority to U.S. Provisional Patent Application No. 63/317,795 entitled LOW-STRAIN MOUNTING METHOD FOR A TRANSPORTABLE OPTICAL RESONATOR filed Mar. 8, 2022 which is incorporated herein by reference for all purposes.

### BACKGROUND OF THE INVENTION

Ultra-stable laser systems are used in a variety of applications including atomic and molecular spectroscopy, metrology, time and frequency standards, gravitational wave detection, and in the manipulation of quantum states of matter. Ultra-stable laser systems are commonly stabilized by locking the output frequency of a laser to a resonance of an optical resonator such as a rigid Fabry-Perot cavity. When using an optical resonator for stabilization, the laser's output is sent into the resonator and a portion of the light is reflected to a photodetector. The output frequency of the laser is then adjusted in real-time to match the resonance frequency of the cavity, which is primarily determined by the spacing between the cavity's mirrors. One important parameter of an optical resonator is its finesse, which is a measure of the quality of the resonance. High finesse resonators are desirable for many applications as they provide a stronger and more narrow resonance, which in turn allows for improved sensitivity and resolution. However, achieving a stable and high-finesse optical resonance cavity can be challenging, as the cavity's optical properties can be affected by various factors such as temperature fluctuations, mechanical vibrations, and thermal properties of the cavity interfaces and coatings. This presents a problem for the creation of a stable optical resonance cavity with a high finesse because it is difficult to maintain the optical resonator performance under various conditions such as those encountered during transportation.

### BRIEF DESCRIPTION OF THE DRAWINGS

Various embodiments of the invention are disclosed in the following detailed description and the accompanying drawings.

FIG. 1 is an illustration of an embodiment of a low strain mounting method for a transportable optical resonator and stabilized laser system.

FIG. 2 is an illustration of a horizontal slice through a silicon spacer support ring for an optical resonator.

FIG. 3A and detail FIG. 3B are illustrations of an embodiment of a low-strain mounting method for a transportable optical resonator.

FIG. 4A and detail FIG. 4B is an illustration of a cavity support ring for an optical resonator.

FIG. 5 is an illustration of a cavity support structure base for an optical resonator and cavity support ring.

FIG. 6A is an illustration of an embodiment of a low-strain mounting method using active clamping for a transportable optical resonator.

FIG. 6B is an illustration of an embodiment of a low-strain mounting method using active clamping for a transportable optical resonator.

FIG. 7 is a flow diagram illustrating an embodiment of a low-strain mounting method for a transportable optical resonator and stabilized laser system.

### DETAILED DESCRIPTION

The invention can be implemented in numerous ways, including as a process; an apparatus; a system; a composition of matter; a computer program product embodied on a computer readable storage medium; and/or a processor, such as a processor configured to execute instructions stored on and/or provided by a memory coupled to the processor. In this specification, these implementations, or any other form that the invention may take, may be referred to as techniques. In general, the order of the steps of disclosed processes may be altered within the scope of the invention. Unless stated otherwise, a component such as a processor or a memory described as being configured to perform a task may be implemented as a general component that is temporarily configured to perform the task at a given time or a specific component that is manufactured to perform the task. As used herein, the term ‘processor’ refers to one or more devices, circuits, and/or processing cores configured to process data, such as computer program instructions.

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

A low-strain mounting method for a transportable optical resonator is disclosed. The low-strain mounting method for a transportable optical resonator comprises an optical resonator, a mount, and a fastener. The optical resonator is comprised of a material with a horizontal plane symmetry where the optical resonator includes a horizontal plane protrusion for mounting and the horizontal plane protrusion includes discrete resonator rotational orientation positions. The mount comprises mounting legs compatible with the horizontal plane symmetry and the mount includes discrete mount rotational orientation positions that correspond to the discrete resonator rotation orientation positions at a plurality of rotational angles. The fastener secures the horizontal plane protrusion of the optical resonator to the mount.

In some embodiments, the material of the optical resonator comprises a crystalline material. For example, the material with the horizontal plane symmetry comprises one of the following: single crystal silicon with a 3-fold symmetry about the <1, 1, 1> axis or sapphire with a 3-fold symmetry about the c-axis. In various embodiments, the horizontal plane symmetry comprises one of the following: a two-fold symmetry, a three-fold symmetry, or a four-fold symmetry.

In some embodiments, the mount comprising mounting legs compatible with the horizontal plane symmetry comprises a plurality of mounting legs arranged to have a rotational symmetry equivalent to the horizontal plane symmetry or an integer multiple of the horizontal plane symmetry. For example, the material of the optical resonator comprises silicon where the horizontal plane symmetry comprises a three-fold symmetry and where the mount comprises three mounting legs. In some embodiments, the fastener comprises a plurality of clamp bars corresponding to the mounting legs. In some embodiments, the mount material is different from the material of the optical resonator (e.g., metal mount and silicon cavity) which will cause differential expansion/contraction on cooling of the system. In some embodiments, the discrete resonator rotation orientation positions and the corresponding discrete mount rotation orientation positions enable differential expansion/contraction with maintaining rotational alignment between the mount and the optical resonator.

In some embodiments, the clamping mechanism is an active clamping mechanism. For example, the mechanism is able to be actuated remotely (e.g., from outside the vacuum chamber) to enable the clamp to be clamping the optical resonator to the mount. In various embodiments, the active clamping mechanism comprises a piezo actuator, a remotely activated screw mechanism, a piezo actuated screw mechanism, a New Focus high vacuum Picomotor™ actuator, a high vacuum linear piezo actuator, or any other appropriate active clamping mechanism.

Atomic frequency standards are of great importance for both scientific and technological applications such as the Global Positioning System (GPS), atomic and molecular spectroscopy, metrology, time and frequency standards, gravitational wave detection, and in the manipulation of quantum states of matter. For example, while the present definition of the second is derived from a microwave transition in cesium atoms, atomic frequency standards based on narrow-linewidth optical transitions now surpass the performance of microwave predecessors in both accuracy and stability. These clocks use the transitions of atoms in the optical regime, which provide much higher precision than the microwave frequencies used in cesium atomic clocks. Additionally, optical clocks are less affected by external factors such as temperature and pressure changes. As a result, it is possible to achieve much higher accuracy and stability with optical atomic clocks than with cesium atomic clocks.

A stable optical resonance cavity with a high finesse is an important part for realizing the optical atomic frequency standards (currently based on narrow-linewidth optical transitions). The finesse of a cavity, which is a measure of the quality factor of the cavity, is determines the width of the resonance peaks and the amount of light that can be stored in the cavity. A high finesse cavity provides a very narrow resonance peak, which allows for more precise measurements of the frequency of light. Additionally, a stable cavity is necessary to maintain the accuracy of the measurement over time (e.g., a photonic flywheel). However, to make such a stable optical resonance cavity, the environmental perturbations to the cavity length need to be reduced or eliminated because the fractional laser frequency fluctuations are proportional the fractional cavity length fluctuations.

In general, the stability of an optical resonance cavity is limited by myriad sources of noise, including thermal noise, mechanical noise, and vibrations. Each of these sources of noise can affect the cavity length and cause variations in the resonance frequency of the cavity. Acceleration-induced cavity length variation is caused by the movement of the cavity relative to its environment. Among many possible perturbations, the acceleration-induced cavity length variation is one of the more important perturbations to control. When the cavity is subjected to acceleration, such as vibrations or mechanical shocks, the cavity length changes, which can cause variations in the resonance frequency. Designs that reduce perturbations to the cavity length are particularly important where the device may experience high acceleration such as in aircrafts or satellites.

While optical resonance cavities can use a variety of different materials for the cavity spacer, silicon has a number of advantages as a spacer material including its low thermal expansion coefficient, high thermal conductivity, and its relatively low cost. Other materials that can be used for the spacer in optical resonance cavities include fused silica, sapphire, and various types of glasses, ceramics, and glass/ceramic mixtures. The choice of material depends on the specific application and the desired properties of the cavity, such as thermal stability, mechanical stability, and optical loss.

Prior approaches to reducing acceleration-induced cavity-length variations include careful selection of cavity body shape and cavity mounting methods. One of the more effective methods for reducing acceleration-induced cavity-length variations mount the cavity spacer vertically to cancel the cavity length changes due to the vertical accelerations. Several vertically mounted double-taper cylinder shape cavities have demonstrated excellent is performance—especially when utilizing silicon single crystalline material at cryogenic temperatures.

A crystalline resonance cavity spacer exhibits rotational symmetry for a chosen orientation of the spacer axis with respect to crystal axes. For example, a silicon spacer with its axis aligned along <1,1,1> silicon crystal direction (the direction with the largest Young's modulus in crystalline silicon) exhibits a 3-fold rotational symmetry. To take advantage of this rotational symmetry, a cavity support structure is selected with the same rotational symmetry. In case of the silicon spacer with its axis along the <1,1,1> crystallographic direction, the selected cavity support structure is a tripod. Detailed analysis shows that the spacer's acceleration sensitivity (i.e., the fractional cavity length change per unity acceleration), depends on the position of the spacer support ring along the spacer axis and the rotation angle of the spacer with respect to the tripod support. In some embodiments, the mount comprising mounting legs compatible with the horizontal plane symmetry comprises a plurality of mounting legs arranged to have a rotational symmetry equivalent to the horizontal plane symmetry or an integer multiple of the horizontal plane symmetry.

In prior art, to find the zero (or minimum) acceleration sensitivity, the silicon spacer is rotated while its acceleration sensitivity is measured. Therefore, there is no constraint in the individual post-based tripod mounting structure to limit the rotation of the spacer so that an infinitesimally small angle could be adjusted to achieve the absolute minimum acceleration sensitivity. In addition, the prior art has no constraint to limit the motion of the spacer along the vertical direction. This lack of vertical constraint is one of the methods to manage the coefficient of thermal expansion mismatch in the process of changing temperature (e.g., changing from room temperature −293 K to a cryogenic temperature <130 K). However, a cavity system with these two unconstrained mounting design features cannot survive the shocks and vibrations in transportation. Thus, the applications of such a system are limited because the cavity system has to be assembled at the location where the system will be used and cannot be moved after assembly. The disclosed low-strain mounting method for a transportable optical resonator overcomes these limitations.

In some embodiments, the disclosed system improves the art by providing a is clamping mechanism that prevents changes in the alignment of the resonant cavity and the mounting of the cavity. This improves the stability of the instrument when shocked or moved.

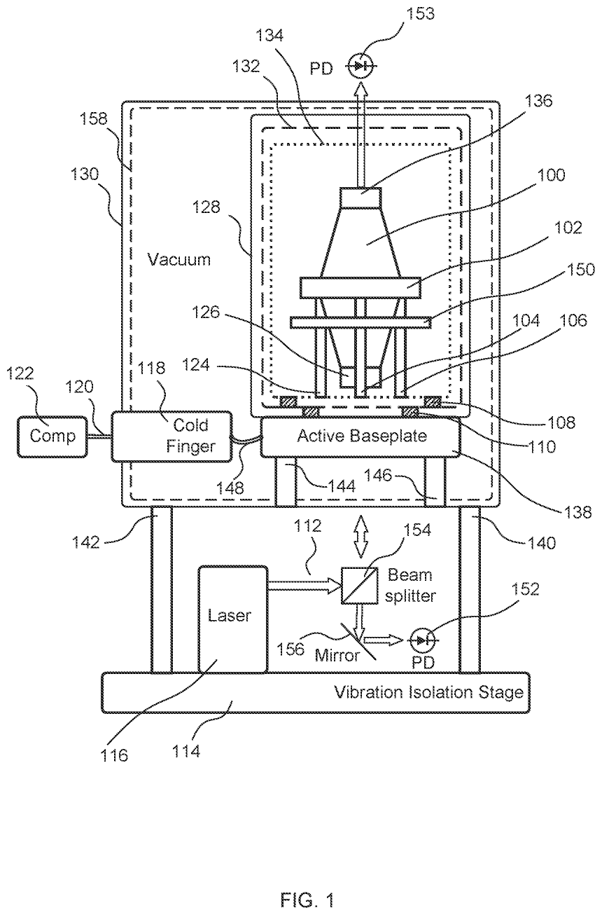

FIG. 1 is an illustration of an embodiment of a low strain mounting method for a transportable optical resonator and stabilized laser system. In the example shown, the transportable optical resonator and stabilized laser system comprises a silicon cavity, a mount for the silicon cavity, a cryostat, a vacuum system, a vibration-isolation platform, and an optical system intended for stabilization.

The silicon cavity comprises silicon cavity spacer 100, spacer support ring 102, mirror 136, and mirror 126. In some embodiments, silicon cavity spacer 100 and spacer support ring 102 are machined from a continuous piece of single-crystal silicon material. In some embodiments, mirror 136 and mirror 126 are machined from a single-crystal silicon material and attached to the silicon cavity spacer with the same orientation of the single crystal silicon as the silicon cavity spacer 100 and spacer support ring 102. In some embodiments, the silicon cavity is operated at a temperature near 123 K, where the coefficient of thermal expansion of silicon crosses zero and the changes that create instrumentation noise due to thermal expansion changes in the fractional length of the cavity are minimized. Similarly, the silicon cavity is operated near 18 K, where the coefficient of thermal expansion of silicon crosses zero. In some embodiments, the silicon cavity is operated at a temperature <18 K where the coefficient of thermal expansion of silicon is very small. The mount for the silicon cavity comprises cavity support structure 124, cavity support structure 104, cavity support structure 106, and cavity support ring 150. In some embodiments, cavity support ring 150 interfaces with silicon spacer support ring 102 in a way that allows for different coefficients of thermal expansion of the two materials.

The cryostat comprises passive shield 134, insulator 108, passive shield 132, insulator 110, active shield 128, active baseplate 138, baseplate mount 144, baseplate mount 146, vacuum enclosure 130, compressor 122, hose 120, cold finger 118, and flexible thermal strap 148. In some embodiments, passive shield 132 and passive shield 134 are made of gold-plated aluminum alloy. In some embodiments, compressor 122 feeds cold nitrogen gas or other coolant both to and returning from hose 120 and cold finger 118. Flexible thermal strap 148 connects the cold finger 118 and active baseplate 138, which supports the silicon cavity. For example, a gas-based cryostat is used to achieve lower vibrational performance than possible with a liquid-based cryostat. In some embodiments, the temperature of the active thermal shield (e.g., active shield 128) is stabilized by a servo loop or servo loops. In some embodiments, the cryostat comprises one or more passive thermal shields (e.g., passive shield 132 and passive shield 134). In some embodiments, passive shield 132 and/or passive shield 134 of the one or more passive thermal shields is separated from active shield 128 using three thermal insulator supports (e.g., three ball supports). In some embodiments, the cryostat comprises active baseplate 138. In some embodiments, cold finger 118 has its own vacuum enclosure, which is attached to vacuum enclosure 130.

In some embodiments, the three thermal radiation shields (e.g., active shield 128, passive shield 132, and passive shield 134) reduce the temperature fluctuations from the cold finger/head and reduce the temperature gradient due to differential thermal loading and cooling. In some embodiments, three-ball contact support (e.g., insulator 108 and/or insulator 110) between each thermal radiation shields allows for kinematic mounting where each successive layer of three-ball contacts is positioned in a progressively wider diameter and rotated 30 degrees relative to the layer above in order to maximize the stack-up stability. In some embodiments, the foot connection of the truss structure (e.g., at base plate mount 144 and base plate mount 146) is clamped in place with a radially positioned dovetailed foot that applies downward force on the post foot but allows for coefficient of thermal expansion (CTE) mismatch between the vacuum can base plate and the support structure. In some embodiments, the active plate thermal connection (e.g., between active baseplate 138 and cold finger 118) allows for the thermal strap/rope connection from the cryocooler to be attached from the top access. In some embodiments, the internal assembly can be disassembled from access through the vacuum can top plate. In some embodiments, the use of plastic balls in three-point contact between active shield 128 and each passive thermal shield (e.g., passive shield 132 and passive shield 134) minimizes parasitic thermal conduction to the cavity and allows for CTE matched kinematic mounting. In some embodiments, the plastic balls are made from Torlon or polyether ether ketone (PEEK) material. In some embodiments, the active and passive shields (e.g., active shield 128, passive shield 132, and passive shield 134) are plated with gold or silver for lower emissivity.

The vacuum system comprises vacuum enclosure 130. The vibration-isolation platform further comprises vibration isolation stage 114, vibration isolation stage support structure 140, and vibration isolation stage support structure 142.

The optical system intended for stabilization comprises laser 116 and input beam 112. For example, phase modulated light in input beam 112 from laser 116 is directed onto the two-mirror (mirror 136 and mirror 126) silicon cavity 100 using beam splitter 154. Light reflected off the cavity is measured by photodetector 152 after passing through beam splitter 154 and reflected off of mirror 156. The resulting electronic signal from photodetector 152 is processed to extract a measure of how far the laser carrier is off resonance with the cavity and is used as feedback for active stabilization of the laser frequency to keep it locked on resonance with the cavity. Light transmitted through the cavity is detected by photodetector 153 for stabilization of the optical power inside the cavity.

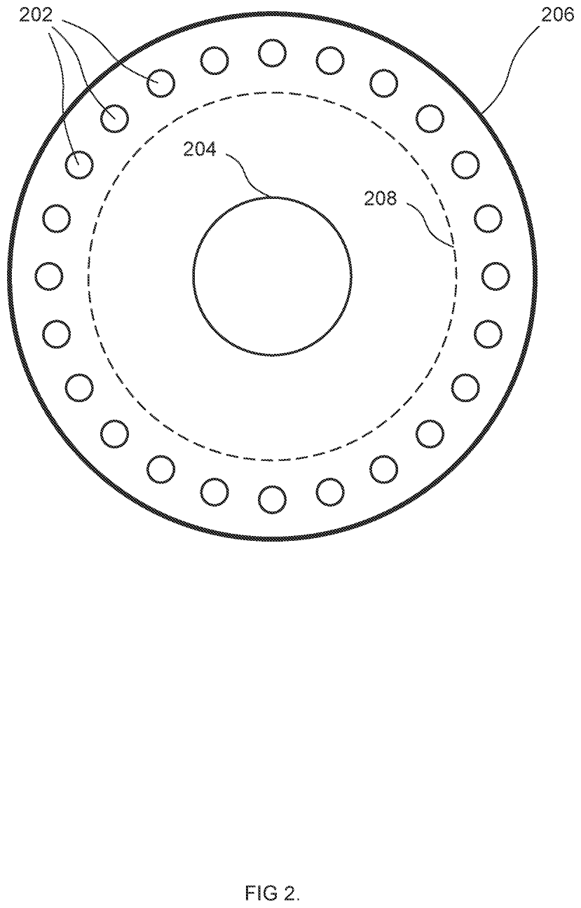

FIG. 2 is an illustration of a horizontal slice through a silicon spacer support ring for an optical resonator. In some embodiments, silicon spacer support ring 102 of FIG. 1 is implemented by silicon spacer support ring 206 of FIG. 2. In the example shown, silicon spacer support ring 206 comprises index holes 202, cavity boundary 204, and silicon transition boundary 208. In some embodiments, silicon spacer support ring 206 is horizontally located at a vertical midsection location of the optical resonator. In various embodiments, silicon spacer support ring 206 is horizontally located slightly above or slightly below a midsection location vertically of the optical resonator in order to minimize acceleration sensitivity of the cavity.

In some embodiments, a plurality of indexed holes 202 (e.g., a through hole) along a circular circumference of the horizontal plane protrusion of the silicon spacer support ring 206 constrain balls for mounting the optical resonator at discrete optical resonator rotational orientation positions to a cavity support structure and constrain the resonator system in 3 degrees of freedom. For example, the discrete resonator rotational orientation positions comprise 3 to 144 positions where the discrete mount rotational orientation positions comprise 3 to 144 positions. In some embodiments, the number of discrete resonator rotation orientation positions is an integer multiple of the horizontal plane symmetry. For example, a cavity spacer with n-fold symmetry, the number of indexed positions is an integer multiple of n. The larger the number of is indexed positions, the finer the resolution of the acceleration sensitivity adjustment. For example, a 210 mm long silicon cavity spacer with a 3-fold symmetry using 72 evenly indexed positions has an expected worst case acceleration sensitivity of 2*10⁻¹² (m s⁻²)⁻¹. In some embodiments, a plurality of indexed v-grooves oriented perpendicular to a circular circumference on a surface of the mount allow relative radial thermal expansion between the optical resonator and the mount. In some embodiments, a plurality of indexed v-grooves oriented perpendicular to a circular circumference on a surface of the mount indicate accuracy of alignment with symmetry axes or vibrational sensitivity. In some embodiments, a plurality of indexed holes (e.g., through holes, indents, holes, etc.) along a circular circumference on the horizontal plane protrusion and a plurality of indexed v-grooves oriented perpendicular to a circular circumference on a surface of the mount constrain the system in 6 degrees of freedom.

In some embodiments, the indexed positions have a preferred orientation with respect to the crystal axes. For example, one of the indexed positions is aligned with crystal axis of <2,−1,−1> in a silicon cavity with its axis along the <1,1,1> direction. In some embodiments, the indexed positions are unevenly distributed but arranged, according to the mounting positions on the cavity support structure such that cavity spacer can be rotationally repositioned by using different sets of indexed positions.

In some embodiments, the indexed positions are implemented by v-grooves instead of holes 202 for constraining the balls for mounting the optical resonator to a cavity support structure. For example, v-grooves are located along the radial direction at each of the desired indexed position at the bottom of the spacer support ring. In some embodiments, the indexed positions can be placed at the bottom of the spacer support ring. In some embodiments, the indexed positions can be placed at the top of the spacer support ring. In some embodiments, the indexed positions can be placed at the cylindrical surface of silicon spacer support ring 206.

In some embodiments, cavity boundary 204 indicates the boundary between the single crystal silicon material of silicon spacer support ring 206 and the voided cavity to provide for laser transmission. For example, laser beam 112 of FIG. 1 is transmitted within cavity boundary 204.

In some embodiments, transition boundary 208 indicates the horizontal plane of is the spacer support ring to the conical section of the optical resonator. For example, silicon spacer support ring 206 and the conical section of the optical resonator are machined from a single crystal silicon material. In some embodiments the conical section is tapered beginning at transition boundary 208 to reduce the inertia and corresponding vibrational noise of silicon spacer support ring 206 and to reduce the acceleration sensitivity of the cavity.

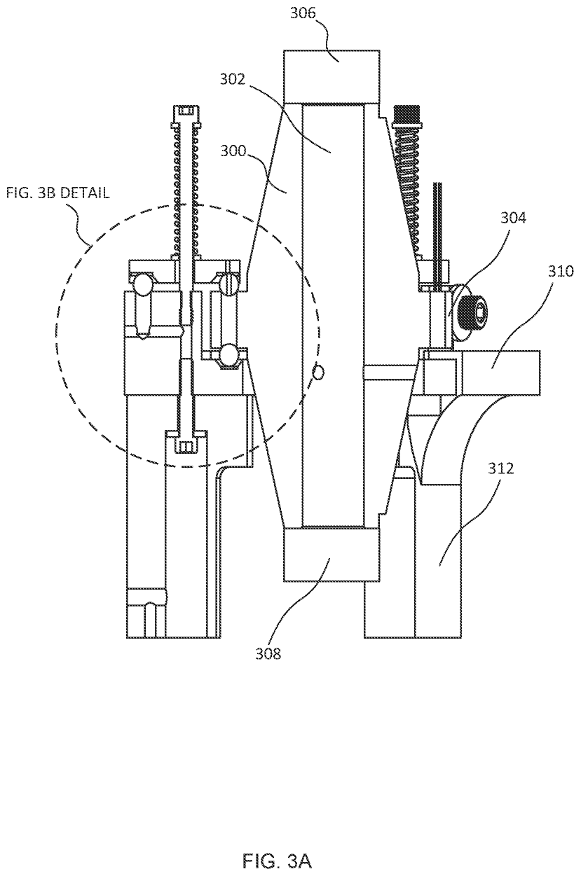

FIG. 3A and detail FIG. 3B are illustrations of an embodiment of a low-strain mounting method for a transportable optical resonator. In some embodiments, optical resonator 300 of FIG. 3A is implemented by optical resonator 100 of FIG. 1. In some embodiments, spacer support ring 304 of FIG. 3A is implemented by spacer support ring 206 of FIG. 2. In the example shown, the transportable optical resonator comprises a silicon cavity and a mounting apparatus for the silicon cavity.

The silicon cavity comprises silicon cavity spacer 300, spacer support ring 304, mirror 306, and mirror 308. In some embodiments, silicon cavity spacer 300 and spacer support ring 304 are machined from a continuous piece of single-crystal silicon material. In some embodiments, mirror 306 and mirror 308 are machined from a single-crystal silicon material and attached to the silicon cavity spacer with the same orientation of the single crystal silicon as the silicon cavity spacer 300 and spacer support ring 304. The mount for the silicon cavity comprises cavity support ring 310 and cavity support structure 312. In some embodiments, cavity support ring 310 interfaces with spacer support ring 304 in a way that constrains the optical resonator system in 3 degrees of freedom while allowing for different coefficients of thermal expansion of the two materials.

FIG. 3B is an illustration of an embodiment of a mounting apparatus for a transportable optical resonator. In the example shown, the mounting apparatus for a transportable optical resonator comprises cavity support structure 364, clamp 358, ball 360, hole 384 to constrain ball 360, v-groove 362, v-groove 366, ball 374, vented ball 354, hole 352 to constrain ball 374 and vented ball 354, v-groove 356, spacer support ring 350, bolt 368, washer 370, and spring 372. In some embodiments, holes 352 correspond to holes 202 from FIG. 2. In some embodiments, holes 352 are through holes. In some embodiments, holes 352 are blind holes.

In some embodiments, the mounting apparatus for a transportable optical resonator prevents rotations and translations perpendicular to the spacer axis of the cavity spacer with respect to the cavity support structure. For example, a set of three holes 352 in spacer support ring 350 contact three balls 374 (e.g., one hole and ball for each of three clamps—for example, clamp 358), each of which contacts one of the v-grooves 366 in the cavity support structure to position the cavity spacer. To search for the minimum acceleration sensitivity, the cavity spacer can be re-positioned using a different set of three holes (e.g., holes 352 of spacer support ring 350). In some embodiments, the ratio of the hole diameter of hole 352 to the ball diameter of ball 374, ball 354, or ball 360 is in the range from 0.15 to 0.95. In some embodiments, ball 354, ball 360, and/or ball 374 are vented with a small through hole 354 so that the air in the holes in cavity support structure 364 or spacer support ring 350, which hold the balls can be pumped out. In some embodiments, the balls are comprised of one of the following materials Torlon, Torlon 4203, PEEK, or PEEK with glass filling. In some embodiments, a first discrete resonator rotational orientation position of the discrete resonator rotational orientation positions corresponds to a first discrete mount rotational orientation position of the discrete mount rotational orientation positions, and where a ball is disposed between the first discrete resonator rotational orientation position and the first discrete mount rotational orientation position.

In some embodiments, the three v-grooves 366 in cavity support structure 364 (e.g., corresponding to each clamp 358) are made along the radial direction and separated by 120°. In some embodiments, each of the three v-grooves 366 in cavity support structure 364 are made along the radial direction and separated by an angle other than 120°. For example, using evenly distributed 72 indexed positions, three balls can be separated by 120°, 115°, and 125°. While a v-groove (e.g., v-groove 366) oriented along the radial direction keeps the cavity spacer in position even when there is a large coefficient of thermal expansion difference between the cavity spacer and the supporting structure. In some embodiments, other orientations of the v-grooves are utilized to prevent rotations and translations of the cavity spacer.

In some embodiments, a v-groove (e.g., instead of hole 352) is made at each of the indexed positions at the bottom of spacer support ring 350 along the radial direction (instead of on cavity support structure 364) and three balls (e.g., similar to ball 374) are embedded in cavity support structure 364 separated by 120° with respect to each other. For example, using three holes at locations corresponding to v-groove 366 in cavity support structure 364 to hold these three balls (e.g., similar to ball 374), one set of three v-grooves in the spacer support ring contact these three balls to position the cavity spacer so that the restrictions applied to the spacer prevent the spacer from rotating and translating transversely. To search for the minimum acceleration sensitivity, the cavity spacer can be re-positioned using a different set of three v-grooves.

In some embodiments, the mounting apparatus for a transportable optical resonator prevents vertical pitch and yaw rotations and vertical translation along the cavity spacer axis of the cavity spacer with respect to the cavity support structure. For example, three holes 352 separated by 120° with respect to each other on the top of spacer support ring 350 hold three balls. In various embodiments, more than three holes are used. Each ball 354 is clamped down from the cavity support structure 364 using clamp 358 (e.g., a plastic clamp) and a screw 368. V-groove 356 along the radial direction at the bottom surface of the clamp 358 constrains vertical movement while allowing radial movement due to thermal expansion differences. The force can be adjusted using screw 368 according to specifications. For example, a higher force can be used if the expected accelerations are high. A strain gauge attached to each clamp reads the force so that the forces on each ball (e.g., ball 360, ball 354, and/or ball 374 at each clamp location) are the same. The downward forces applied to each ball (e.g., ball 360, ball 354, and/or ball 374 at each clamp location) prevent pitch and yaw rotations and vertical translation of the cavity spacer with respect to the cavity support structure.

While a v-groove oriented along the radial direction keeps the cavity spacer in position even when there is a large coefficient of thermal expansion difference between the cavity spacer and the supporting structure, in some embodiments, other orientations of the v-grooves are utilized to prevent rotations and translations of the cavity spacer. In some embodiments, balls 354 are vented so that the air in the blind holes can be pumped out. In some embodiments, the ratio of the hole diameter in ball 354 to the ball diameter is in the range from 0.15 to 0.95.

In some embodiments, three v-grooves are made on the top of the spacer support ring 350 (instead of on clamp 358) along the radial direction for each of the index positions. The v-grooves are separated by the number of indexed positions with respect to each other. Each v-groove contacts a ball which is clamped down from the cavity support structure by using clamp 358 (e.g., a plastic clamp) and a screw 368. Clamp 358 has a hole (a blind hole or a through hole) which holds the ball (e.g., a ball corresponding to ball 354). The force can be adjusted using screw 368 according to specifications. For example, a higher force can be used if the expected accelerations are high. A strain gauge attached to each clamp reads the force so that the forces on each ball are the same. The downward forces applied to each ball prevent pitch and yaw rotations and vertical translation of the cavity spacer with respect to the cavity support structure. In some embodiments, a spring (e.g., spring 372) and a shoulder screw (e.g., screw 368) is used to set the downward forces applied to each of the balls to allow calibration of the force before assembly and to provide tolerance for differences in the vertical coefficient of thermal expansion of the two materials. For example, the variations of the spring constants of the springs can be pre-measured and the lengths of the springs can be pre-lapped to match the forces among three springs. The force can be changed using a shoulder screw with a different length or choosing a different spring. In some embodiments, a clamp bar of the plurality of clamp bars is spring loaded. In some embodiments, a first ball separates a first end of the clamp bar from the mount and a second ball separates a second end of the clamp bar from the horizontal plane protrusion. In some embodiments, the first ball rests in a v-groove on the mount. In some embodiments, the v-groove is oriented radially. In some embodiments, the second ball rests in an indexed hole (e.g., a through hole, an indent, a hole, etc.) along a circular circumference on the horizontal plane protrusion. In some embodiments, a clamp bar of the plurality of clamp bars is spring loaded, wherein a force associated with a spring for being spring loaded is controlled using a shoulder screw.

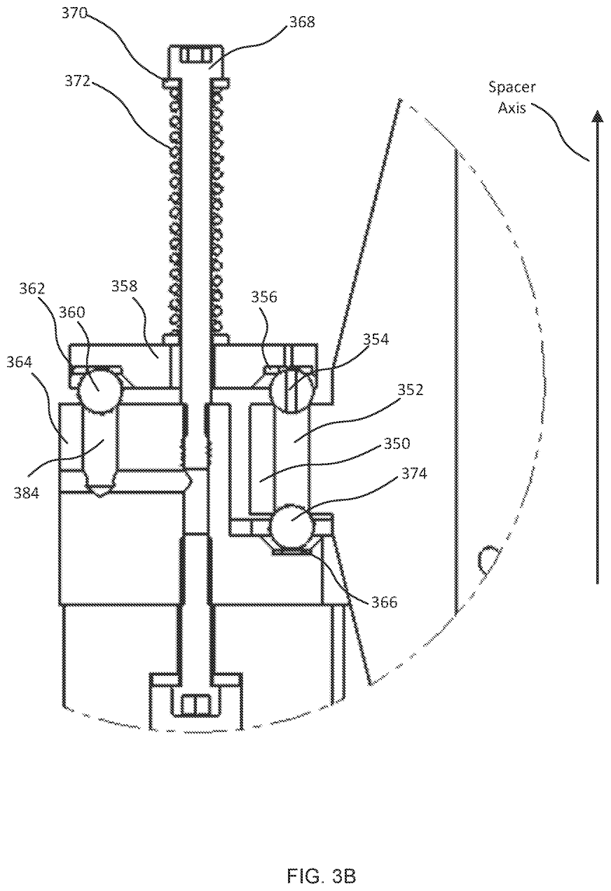

FIG. 4A and detail FIG. 4B is an illustration of a cavity support ring for an optical resonator. In some embodiments, cavity support ring 400 of FIG. 4A is used to implement cavity support ring 150 of FIG. 1. In the example shown, the optical resonator comprises silicon cavity spacer 402, spacer support ring 404, mirror 406, and mirror 408. In the example shown, cavity support ring 400 is machined from a single piece of metal (or plastic or other materials) to reduce twist and sway. For example, a one-piece cavity support ring is more stable than individual posts. The optical resonator is clamped to cavity support ring 400 using clamp 410. Recess 414, recess 416, and recess 418 are cut into the bottom of cavity support ring 400 to reduce the contacting area to the cavity support structure base and reduce the overall structure thermal conductivity.

Detail FIG. 4B is an illustration of a slice through the top surface 420 of cavity support ring 400. In some embodiments, radial v-groove 422, v-groove 424, v-groove 426 are machined into the top surface 420 of cavity support ring 400 to constrain a ball and reduce the effects of any radial coefficient of thermal expansion mismatch between the cavity support ring and the thermoplastic cavity support structure. Top surface 420 further comprises bolt hole 430, bolt hole 440, and bolt hole 450, which are threaded for clamping clamps (e.g., clamp 410). Top surface 420 further comprises holes (e.g., hole 432, hole 442, and 452) to constrain a ball for the other end of clamps.

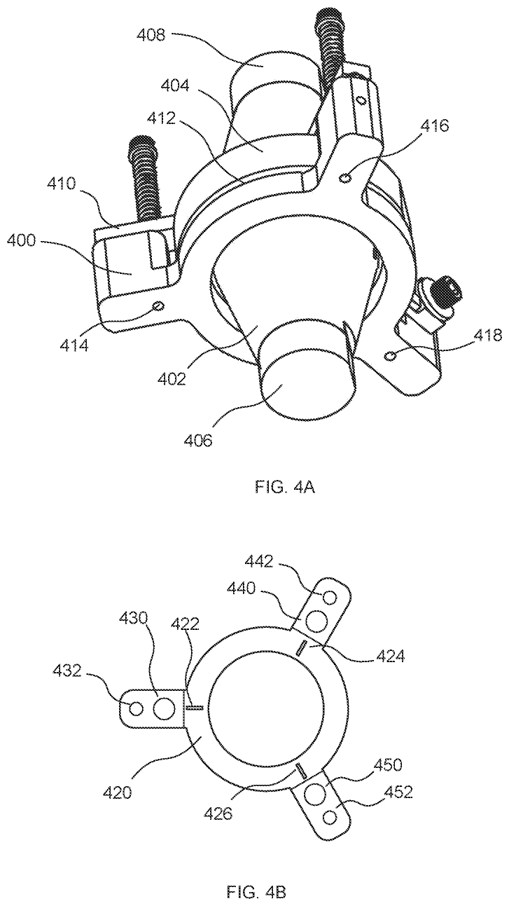

FIG. 5 is an illustration of a cavity support structure base for an optical resonator and cavity support ring. In some embodiments, cavity support structure 500 of FIG. is implemented by cavity support structure 124, cavity support structure 104, and/or cavity support structure 106 of FIG. 1. In the example shown, the optical resonator comprises silicon cavity spacer 504, mirror 506, and mirror 508. In some embodiments, cavity support ring 502 is machined from a single piece of metal (or other materials) and fastened to cavity support structure 500. Cavity support structure 500 is machined from a single piece of thermal insulation material. For example, a one-piece structure improves the stiffness, increases the eigenfrequencies, increases the damping factor, and maintains low thermal conductivity of the cavity support structure. In various embodiments, the insulation material comprises Torlon, PEEK, PEEK with 30% glass filling, or any other appropriate thermoplastic material. In some embodiments, recess 510, recess 512, and recess 514 are cut into the bottom of cavity support structure 500 to reduce the contacting area to the supporting inner passive shield in order to reduce the overall structure's thermal conductivity. In some embodiments, the inner passive shield is passive shield 134 of FIG. 1.

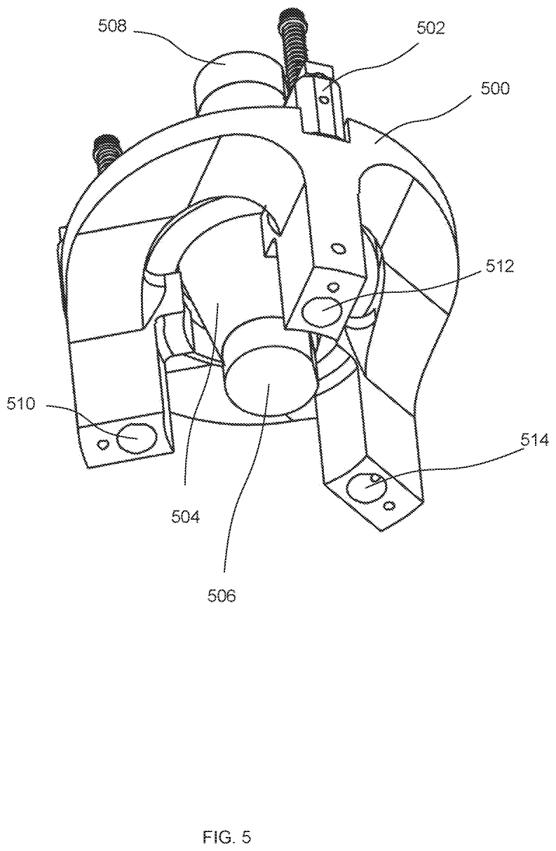

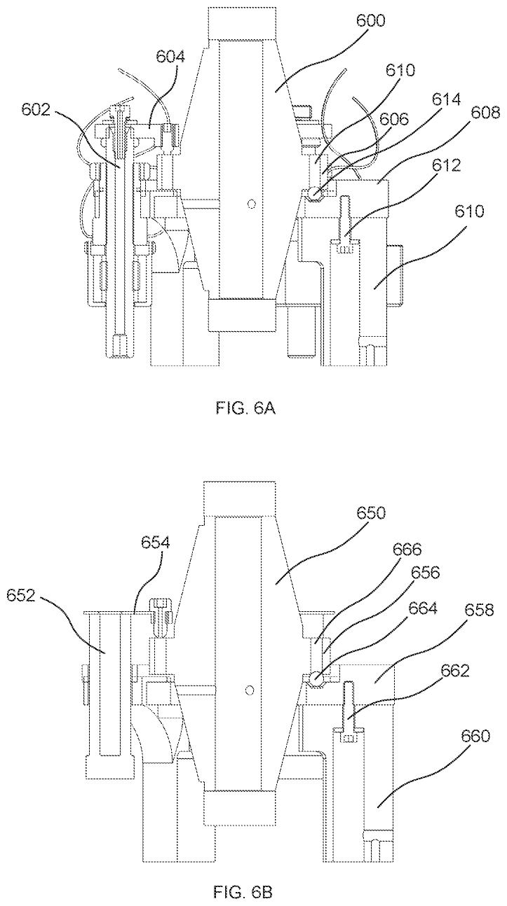

FIG. 6A is an illustration of an embodiment of a low-strain mounting method using active clamping for a transportable optical resonator. In some embodiments, optical resonator 600 of FIG. 6A is used to implement optical resonator 100 of FIG. 1. In some embodiments, the clamping of FIG. 6A is used in place of clamp 358 of FIG. 3B and/or clamp 410 of FIG. 4. In the example shown, the transportable optical resonator system comprises a silicon cavity and a mounting apparatus utilizing active clamping of the silicon cavity with an ultra-high vacuum compatible motor as an actuator. In some embodiments, the motor has an encoder for reading and determining the position. In some embodiments, the motor comprises a Picomotor. The transportable optical resonator system comprises optical resonator 600, ultra-high vacuum compatible Picomotor actuator 602, cavity spacer support clamp 604, silicon cavity spacer support ring 606, cavity support ring 608, cavity support structure 610, and fastener 612. In some embodiments, the fastener comprises a linear actuator corresponding to a mounting leg of the plurality mounting legs. In some embodiments, the linear actuator is a lead zirconate titanate (PZT) actuator. In some embodiments, the fastener comprises a fastener corresponding to each of the mounting legs. In some embodiments, the actuators can be controlled to clamp or not clamp. In some embodiments, there is built-in compliance (such as a spring-loaded tip) between the clamp and the optical cavity.

Active clamping of optical resonator 600 allows for silicon cavity spacer support ring 606 to be returned to a zero-stress state during operation. In some embodiments, cavity spacer support clamp 604 and ultra-high vacuum compatible Picomotor actuator 602 is actuated during transport. In some embodiments, the cavity spacer support clamp 604 is actively actuated if shocks or vibrations are sensed. In contrast, the passive mounting clamping method of FIG. 3A and/or FIG. 3B relies on spring-loaded clamps which keep constant pressure on silicon cavity spacer support ring 606 and locates silicon cavity spacer support ring 606 relative the ball contacts 614 This requires constantly touching silicon cavity spacer support ring 606 on the top surface and applying a downward force onto silicon cavity spacer support ring 606 sufficient to withstand any acceleration, shock, or jerk impulse into the system.

In some embodiments, the actuators (e.g., such as ultra-high vacuum compatible Picomotor actuator 602) are mounted on cavity support structure 610 (e.g., an insulating base structure made of PEEK) insulating the cavity support ring 608 from any thermal inputs from the actuator wires. In some embodiments, the actuators provide downward pressure onto the silicon cavity spacer support ring 606 when ultra-high vacuum compatible Picomotor actuator 602 is contracted and releases pressure when ultra-high vacuum compatible Picomotor actuator 602 is extended. When not needed, the actuators (e.g., ultra-high vacuum compatible Picomotor actuator 602) lift the clamps upwards such that they do not contact silicon cavity spacer support ring 606. Optical resonator 600 is constrained in the vertical direction by gravity and in the horizontal direction by the bottom ball 612 contact in the cavity spacer hole or slot 610.

FIG. 6B is an illustration of an embodiment of a low-strain mounting method using active clamping for a transportable optical resonator. In some embodiments, optical resonator 650 of FIG. 6B is used to implement optical resonator 100 of FIG. 1. In some embodiments, the clamping of FIG. 6B is used in place of clamp 358 of FIG. 3B and/or clamp 410 of FIG. 4. In the example shown, the transportable optical resonator system comprises a silicon cavity and a mounting apparatus utilizing active clamping of the silicon cavity with an ultra-high vacuum compatible linear actuator. In some embodiments, the ultra-high vacuum compatible linear actuator comprises a PZT linear actuator. The transportable optical resonator system comprises optical resonator 650, ultra-high vacuum compatible PZT linear actuator 652, clamp 654, silicon cavity spacer support ring 656, cavity support ring 658, cavity support structure 660, and fastener 662. In some embodiments, clamp 654 has built-in compliance. For example, clamp 654 is made of a piece of springy steel sheet. In some embodiments, the fastener comprises a PZT actuator corresponding to a mounting leg of the plurality mounting legs. In some embodiments, the fastener comprises a fastener corresponding to each of the mounting legs. In some embodiments, the actuators can be controlled to clamp or not clamp.

Active clamping of optical resonator 650 allows for silicon cavity spacer support ring 656 to be returned to a zero-stress state during operation. In some embodiments, cavity spacer support clamp 654 and ultra-high vacuum compatible PZT linear actuator 652 is actuated during transport. In some embodiments, the cavity spacer support clamp 654 is actively actuated if shocks or vibrations are sensed. In contrast, the passive mounting clamping method of FIG. 3A and/or FIG. 3B relies on spring-loaded clamps which keep constant pressure on silicon cavity spacer support ring 658 and locates silicon cavity spacer support ring 656 relative the ball contacts 664. This requires constantly touching silicon cavity spacer support ring 656 on the top surface and applying a downward force onto silicon cavity spacer support ring 656 sufficient to withstand any acceleration, shock, or jerk impulse into the system.

In some embodiments, the actuators (e.g., such as ultra-high vacuum compatible PZT linear actuator 652) are mounted on cavity support structure 660 (e.g., an insulating base structure made of polyether ether ketone (PEEK)) insulating the cavity support ring 658 from any thermal inputs from the actuator wires. In some embodiments, the actuators provide downward pressure onto the silicon cavity spacer support ring 656 when ultra-high vacuum compatible PZT linear actuator 652 is contracted and releases pressure when ultra-high vacuum compatible PZT linear actuator 652 is extended. When not needed, the actuators (e.g., ultra-high vacuum compatible PZT linear actuator 652) lift the clamps upwards such that they do not contact silicon cavity spacer support ring 656. Optical resonator 650 is constrained in the vertical direction by gravity and in the horizontal direction by the bottom ball 664 contact in the cavity spacer hole or slot 666.

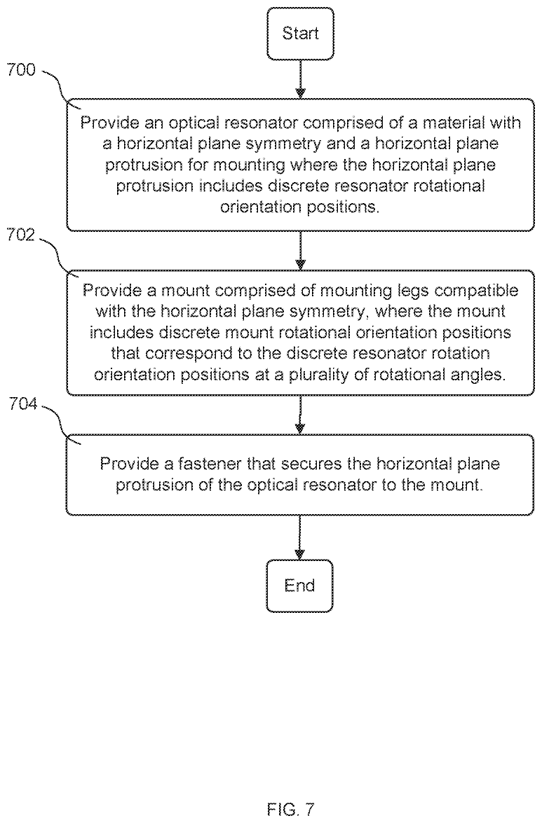

FIG. 7 is a flow diagram illustrating an embodiment of a low-strain mounting method for a transportable optical resonator and stabilized laser system. In some embodiments, the process of FIG. 7 is associated with the system of FIG. 1. In the example shown, in 700, an optical resonator comprised of a material with a horizontal plane symmetry and a horizontal plane protrusion for mounting is provided, where the horizontal plane protrusion includes discrete resonator rotational orientation positions. For example, a silicon cavity spacer and spacer support ring are machined from a continuous piece of single-crystal silicon material. Two mirrors are additionally machined from a single-crystal silicon material and attached to the silicon cavity spacer with the same orientation of the single crystal silicon as the silicon cavity spacer and spacer support ring. In some embodiments, the silicon cavity is operated at a temperature near 123 K, where the coefficient of thermal expansion of silicon crosses zero and the corresponding noise due to thermal expansion changes in the fractional length of the cavity are minimized. In some embodiments, a plurality of indexed holes (e.g., a through hole, an indent, a hole, etc.) along a circular circumference of the horizontal plane protrusion of the silicon spacer constrain balls for mounting the optical resonator at discrete optical resonator rotational orientation positions to a cavity support structure and constrain the resonator system from motion in each of the 3 degrees of possible motion.

In 702, a mount comprised of mounting legs compatible with the horizontal plane symmetry is provided, where the mount includes discrete mount rotational orientation positions that correspond to the discrete resonator rotation orientation positions at a plurality of rotational angles. For example, the discrete resonator rotation orientation positions have a preferred orientation with respect to the crystal axes, where one of the indexed positions is aligned with crystal axis of <2,−1,−1> in a silicon cavity with its axis along the <1,1,1> direction. In some embodiments, three V-grooves in the cavity support structure are made along the radial direction and separated by 120°. V-grooves oriented along the radial direction keep the cavity spacer in position even when there is a large coefficient of thermal expansion difference between the cavity spacer and the supporting structure. In some embodiments, the discrete resonator rotation orientation positions are unevenly distributed but arranged, according to the mounting positions on the cavity support structure such that cavity spacer can be rotationally repositioned by using different sets of indexed positions.

In 704, a fastener that secures the horizontal plane protrusion of the optical resonator to the mount is provided. For example, the fastener, which secures the horizontal plane protrusion of the optical resonator to the mount for a transportable optical resonator, prevents rotations and translations perpendicular to the spacer axis of the cavity spacer with respect to the cavity support structure. In some embodiments, a set of three holes in the spacer support ring contact three balls, each of which contacts one of the v-grooves in the cavity support structure to position the cavity spacer.

Although the foregoing embodiments have been described in some detail for purposes of clarity of understanding, the invention is not limited to the details provided. There are many alternative ways of implementing the invention. The disclosed embodiments are illustrative and not restrictive.

What is claimed is:

1. A system, comprising:
an optical resonator, wherein the optical resonator is comprised of a material with a horizontal plane symmetry, wherein the optical resonator includes a horizontal plane protrusion for mounting, and wherein the horizontal plane protrusion includes discrete resonator rotational orientation positions;
a mount, wherein the mount comprises mounting legs compatible with the horizontal plane symmetry, and wherein the mount includes discrete mount rotational orientation positions that correspond to the discrete resonator rotation orientation positions at a plurality of rotational angles; and
a fastener, wherein the fastener secures the horizontal plane protrusion of the optical resonator to the mount.

2. The system of claim 1, wherein the material of the optical resonator comprises a crystalline material.

3. The system of claim 2, wherein the material with the horizontal plane symmetry comprises one of the following: single crystal silicon with a 3-fold symmetry or sapphire with a 3-fold symmetry about the c-axis.

4. The system of claim 1, wherein the horizontal plane symmetry comprises one of the following: a two-fold symmetry, a three-fold symmetry, or a four-fold symmetry.

5. The system of claim 1, wherein the mount comprising mounting legs compatible with the horizontal plane symmetry comprises a plurality of mounting legs arranged to have a rotational symmetry equivalent to the horizontal plane symmetry or an integer multiple of the horizontal plane symmetry.

6. The system of claim 1, wherein the discrete resonator rotational orientation positions are located using a plurality of indexed holes along a circular circumference on the horizontal plane protrusion.

7. The system of claim 1, wherein the discrete mount rotational orientation positions are located using a plurality of indexed v-grooves oriented perpendicular to a circular circumference on a surface of the mount.

8. The system of claim 1, wherein a first discrete resonator rotational orientation position of the discrete resonator rotational orientation positions corresponds to a first discrete mount rotational orientation position of the discrete mount rotational orientation positions, and wherein a ball is disposed between the first discrete resonator rotational orientation position and the first discrete mount rotational orientation position.

9. The system of claim 8, wherein the ball has at least one hole for venting under vacuum.

10. The system of claim 1, wherein the fastener comprises a plurality of clamp bars corresponding to the mounting legs.

11. The system of claim 10, wherein the fastener comprises a linear actuator.

12. The system of claim 11, wherein the linear actuator comprises a PZT actuator.

13. The system of claim 10, wherein the fastener comprises a motor.

14. The system of claim 13, wherein the motor comprises a Picomotor.

15. The system of claim 10, wherein a clamp bar of the plurality of clamp bars is spring loaded.

16. The system of claim 15, wherein a force associated with a spring for being spring loaded is controlled using a shoulder screw.

17. The system of claim 10, wherein a first ball separates a first end of the clamp bar from the mount and wherein a second ball separates a second end of the clamp bar from the horizontal plane protrusion.

18. The system of claim 17, wherein the first ball rests in a v-groove on the mount.

19. The system of claim 18, wherein the v-groove is oriented radially.

20. The system of claim 17, wherein the second ball rests in an indexed hole along a circular circumference on the horizontal plane protrusion.

21. The system of claim 1, further comprising one or more passive thermal shields.

22. The system of claim 1, further comprising one or more active thermal shields.

23. The system of claim 1, wherein a passive thermal shields of the one or more passive thermal shields is separated from an active thermal shield using three thermal insulator supports.

24. The system of claim 1, further comprising an active baseplate.

25. A method, comprising:
providing an optical resonator, wherein the optical resonator is comprised of a material with a horizontal plane symmetry, wherein the optical resonator includes a horizontal plane protrusion for mounting, and wherein the horizontal plane protrusion includes discrete resonator rotational orientation positions;
providing a mount, wherein the mount comprises mounting legs compatible with the horizontal plane symmetry, and wherein the mount includes discrete mount rotational orientation positions that correspond to the discrete resonator rotation orientation positions at a plurality of rotational angles; and
providing a fastener, wherein the fastener secures the horizontal plane protrusion of the optical resonator to the mount.
